(19) United States
(12) Patent Application Publication
(10) Pub. No.: US 2018/0173288 A1
(43) Pub. Date: Jun. 21, 2018

(54) MULTI POWER DOMAINS TO REDUCE OCV USING CPR INFRASTRUCTURE

(71) Applicant: QUALCOMM Incorporated, San Diego, CA (US)

(72) Inventors: Xiongfei Meng, Carlsbad, CA (US); Pranjal Srivastava, San Diego, CA (US); Patrick Drennan, Gilbert, AZ (US)

(21) Appl. No.: 15/385,529

(22) Filed: Dec. 20, 2016

(51) Int. Cl. G06F 1/32; H03K 3/03

(52) U.S. Cl. CPC G06F 1/324; H03K 3/0315

(57) ABSTRACT

According to certain aspects, a system includes frequency measurement devices distributed across a power domain on a chip, wherein the power domain is divided into multiple power sub-domains, and each of the power sub-domains includes a respective subset of the frequency measurement devices. The system also includes a power manager. For each of the power sub-domains, the power manager is configured to receive frequency measurements from the respective subset of the frequency measurement devices, and determine a supply voltage setting for the power sub-domain based on the received frequency measurements from the respective subset of the frequency measurement devices.

### BACKGROUND

### Field

Aspects of the present disclosure relate to on chip variation (OCV), and more particularly, to multi power domains that account for OCV.

### Background

On-chip variation (OCV) refers to variation on a chip (e.g., variation in gate dimensions, oxide thicknesses, metal layer thicknesses, implant doses, etc.) due to process variation. OCV causes the switching speeds or delays of devices on the chip to vary, which can lead to timing errors if not properly taken into account. OCV for advanced technology processes (e.g., 14 nm and 10 nm) is high, and is expected to be an increasingly dominate phenomenon for future technology nodes.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

A first aspect relates to a system. The system includes frequency measurement devices distributed across a power domain on a chip, wherein the power domain is divided into multiple power sub-domains, and each of the power sub-domains includes a respective subset of the frequency measurement devices. The system also includes a power manager. For each of the power sub-domains, the power manager is configured to receive frequency measurements from the respective subset of the frequency measurement devices, and determine a supply voltage setting for the power sub-domain based on the received frequency measurements from the respective subset of the frequency measurement devices.

A second aspect relates to a method for power management of a chip. The chip includes frequency measurement devices distributed across a power domain on the chip, wherein the power domain is divided into multiple power sub-domains, and each of the power sub-domains includes a respective subset of the frequency measurement devices. The method includes, for each of the power sub-domains, performing the steps of receiving frequency measurements from the respective subset of the frequency measurement devices, and determining a supply voltage setting for the power sub-domain based on the received frequency measurements from the respective subset of the frequency measurement devices.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 shows an example of a core power reduction (CPR) infrastructure on a chip according to certain aspects of the present disclosure.

FIG. 2 shows an exemplary implementation of a ring oscillator according to certain aspects of the present disclosure.

FIG. 3 shows an exemplary spatial performance map for a chip according to certain aspects of the present disclosure.

FIG. 4 shows the exemplary spatial performance map in three dimensions according to certain aspects of the present disclosure.

FIG. 5 shows the exemplary spatial performance map in which a power domain is split into multiple power sub-domains according to certain aspects of the present disclosure.

FIG. 6 shows an exemplary chip including multiple power sub-domains according to certain aspects of the present disclosure.

FIG. 7 shows an exemplary measurement device according to certain aspects of the present disclosure.

FIG. 8 shows an exemplary interface between two power sub-domains according to certain aspects of the present disclosure.

FIG. 9 is a flowchart illustrating an exemplary method for power management of a chip according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

On-chip variation (OCV) has a random statistical component and a spatial component. The random statistical component comes from random statistical variation, which may be reduced by increasing the depth of a signal path (i.e., increasing the number of devices (e.g., logic gates) in the path). This is because increasing the number of devices in series cancels out random statistical variation (e.g., fast devices and slow devices cancel each other out). Random statistical variation may be modeled using parametric on-chip variation (POCV) modeling techniques.

The spatial component comes from spatial variation across the chip (e.g., differences in switching speeds or delays of devices at different locations on the chip). Spatial variation on a chip may be measured using multiple ring oscillators of identical or substantially identical structure distributed across the chip, as discussed further below.

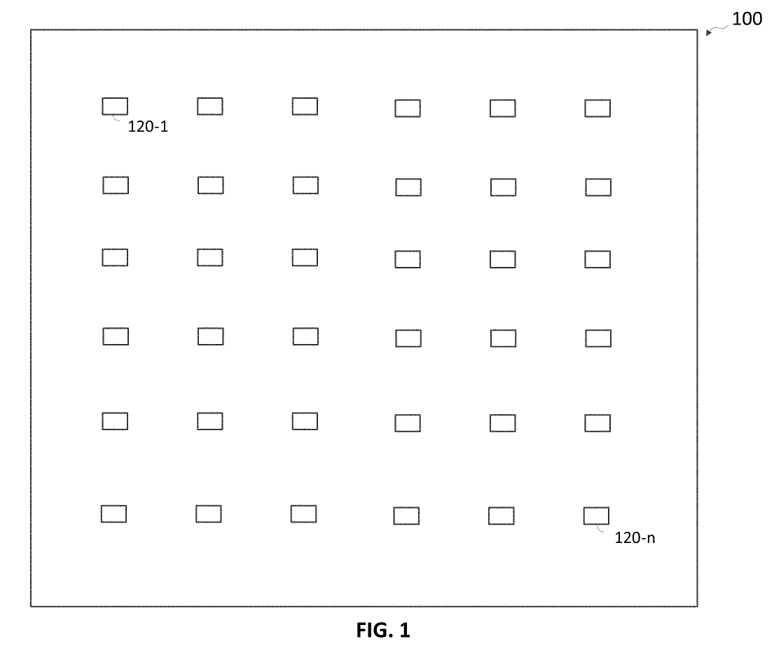

FIG. 1 shows an example of a core power reduction (CPR) infrastructure on a chip 100 (die) according to certain aspects. The CPR infrastructure includes multiple on-chip ring oscillators 120-1 to 120-n (depicted as rectangles) distributed across the chip 100. In the example shown in FIG. 1, the ring oscillators 120-1 to 120-n are distributed uniformly across the chip 100. However, it is to be appreciated that the present disclosure is not limited to this example. For example, the ring oscillators 120-1 to 120-n may be distributed non-uniformly due to constraints on where the ring oscillators can be placed on the chip 100. For instance, it may not be possible to place a ring oscillator in an area of the chip that is densely populated by functional logic gates.

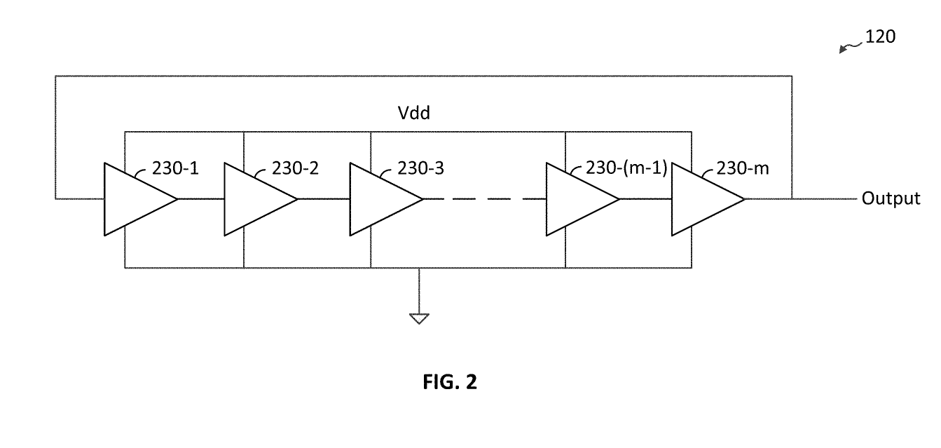

FIG. 2 shows an exemplary implementation of one of the ring oscillators 120. In this example, the ring oscillator 120 includes an odd number of inverters 230-1 to 230-m coupled in series, in which the output of the last inverter 230-m is coupled to the input of the first inverter 230-1 to form a ring (closed loop) that oscillates. The oscillation frequency of the ring oscillator 120 depends on the switching speeds of the inverters 230-1 to 230-m, which are affected by OCV. Thus, the frequency of the ring oscillator 120 provides a measurement of the effect of OCV on performance, as discussed further below.

The inverters 230-1 to 230-m may be implemented with complementary metal-oxide semiconductor (CMOS) inverters, NAND gates, NOR gates, etc. For example, an inverter may be implemented with a two-input NAND gate, in which one of the inputs of the NAND gate is held high. In this example, the NAND gate functions as an inverter that inverts the signal at the other input of the NAND gate and outputs the resulting inverted signal at the output of the NAND gate.

Each of the ring oscillators 120-1 to 120-n is preferably implemented using the same design (e.g., the exemplary design in FIG. 2) so that there is no variation among the ring oscillators due to differences in design. Also, each ring oscillator may be deep (e.g., include 30 or more inverting stages (e.g., inverters)) to reduce random statistical variation among the ring oscillators 120-1 to 120-n. The large depth of the ring oscillators 120-1 to 120-n helps ensure that the dominate component of variation among the ring oscillators 120-1 to 120-n is spatial variation. This enables the measurement of spatial variation across the chip 100 using frequency measurements of the ring oscillators 120-1 to 120-n, as discussed further below.

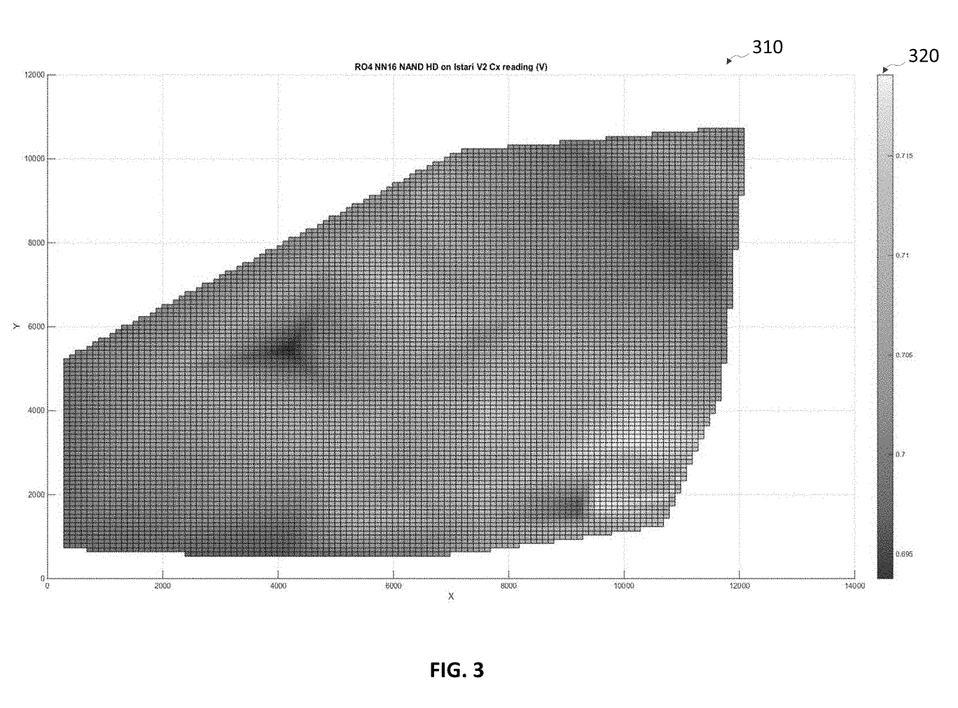

FIG. 3 shows an exemplary spatial performance map 310 for the chip 100 based on frequency measurements of the ring oscillators 120-1 to 120-n. In this example, the performance map 310 shows the minimum supply voltage needed to meet a target performance (target frequency in this example) at different locations on the chip. The x axis and y axis indicate location on the chip using x-y coordinates, and the scale 320 indicates the minimum supply voltage needed to meet the target frequency, which varies from 0.695V to 0.72V across the chip in this example.

The spatial performance map 310 may be generated by measuring the frequencies of the ring oscillators 120-1 to 120-n as the supply voltage is varied, and comparing the measured frequencies with the target frequency. The supply voltage can be adjusted to bring measured frequencies equal. A higher supply voltage will speed up a slower ring oscillator to the target frequency, and a lower supply voltage will slow down a faster ring oscillator. For each of the ring oscillators, the lowest (minimum) supply voltage at which the measured frequency of the ring oscillator meets the target frequency may be determined. This information may be used to construct the performance map 310 shown in FIG. 3.

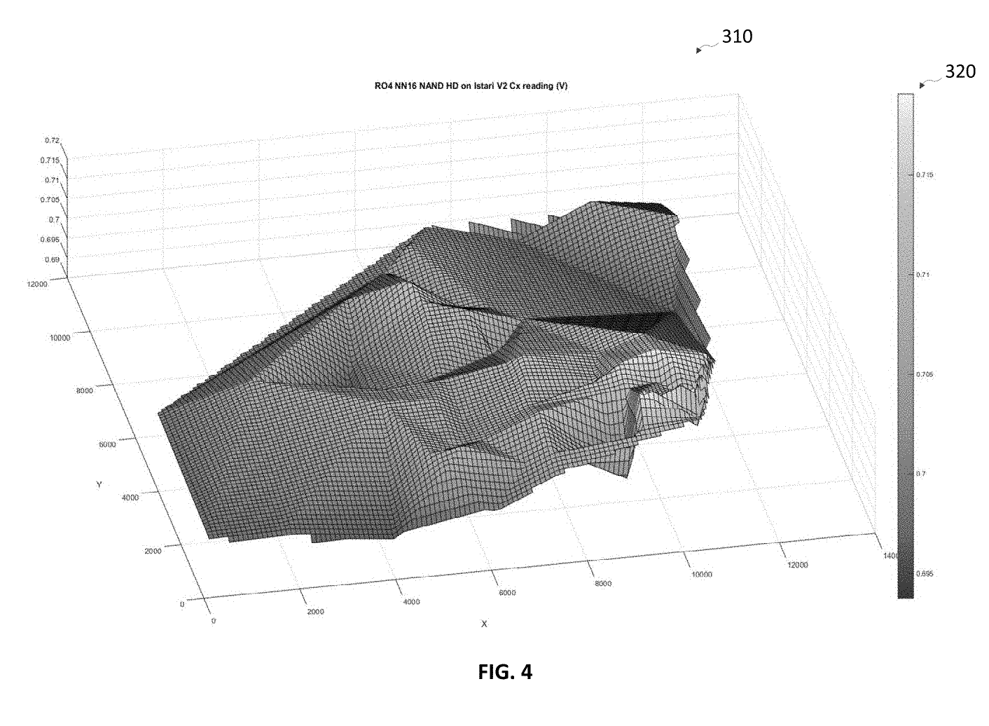

As shown in FIG. 3, the minimum supply voltage needed to meet the target frequency varies spatially across the chip (die). FIG. 4 shows the performance map 310 in three dimensions, in which the z axis corresponds to the minimum supply voltage needed to meet the target frequency. As shown in FIG. 4, the performance map 310 includes valleys and mountains. The valleys correspond to areas of the chip with faster devices requiring lower supply voltages to meet the target frequency, and the mountains correspond to areas of the chip with slower devices requiring higher supply voltages to meet the target frequency. In this example, the range of spatial variation across the chip (die) is close to 30 mV.

It is to be appreciated that the exemplary spatial performance map 310 shown in FIGS. 3 and 4 is for a particular chip (die), and that the spatial performance maps for multiple chips may vary from chip-to-chip (die-to-die). For example, the locations and/or heights of the mountains and valleys in the spatial performance maps may vary from chip-to-chip (die-to-die).

On a conventional chip, core logic on the chip is powered in a single power domain (e.g., CX domain) by a single supply voltage. In this regard, the supply voltage may be set to the largest minimum supply voltage determined for the power domain, which corresponds to the highest mountain in the spatial performance map 310. This is done to ensure that the target performance (e.g., target frequency) is meet across the power domain.

A drawback of this approach is that it sets the supply voltage for the entire power domain based on the area with the largest minimum supply voltage. In other words, the largest minimum supply voltage dictates the supply voltage for the entire power domain, even though other areas of the chip may have lower minimum supply voltages. As a result, more power is consumed in these areas than needed to meet the target performance (e.g., target frequency), which translates into increased power.

Embodiments of the present disclosure reduce power by dividing (splitting) a power domain (e.g., CX domain) on a chip into multiple power sub-domains, and independently setting the supply voltage for each sub-domain. For each sub-domain, the largest minimum supply voltage in the sub-domain for meeting a target performance (e.g., target frequency) is determined. The supply voltage for each sub-domain is then set based on the largest minimum supply voltage determined in the sub-domain. Thus, the supply voltage for each sub-domain is determined based on the largest minimum supply voltage in the sub-domain, and not by the largest minimum supply voltage across all of the sub-domains, as is the case in the prior approach discussed above.

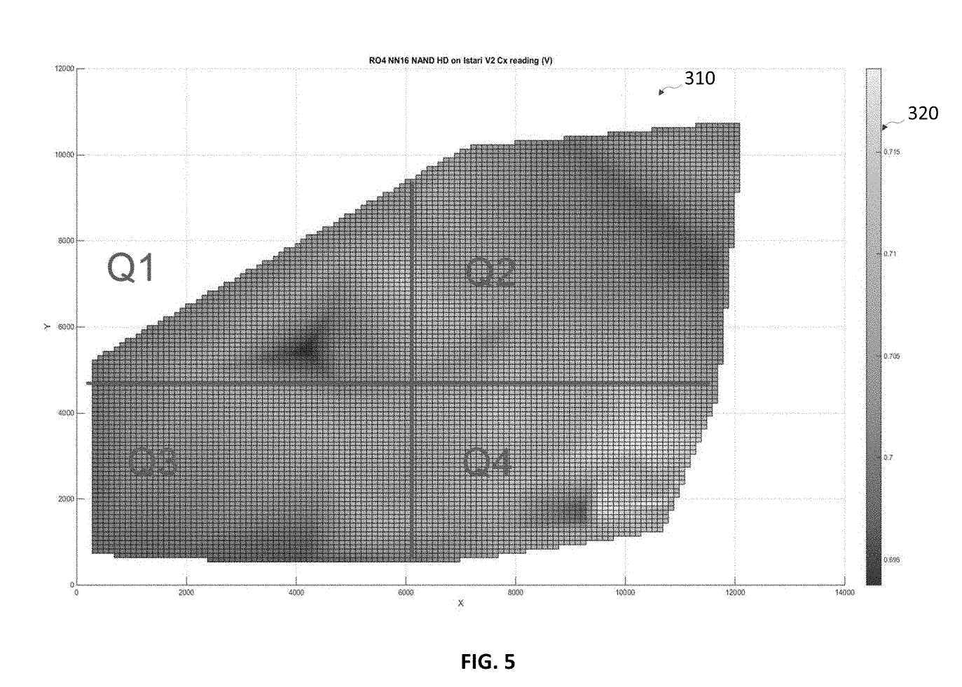

In this regard, FIG. 5 shows the spatial performance map 310 with the power domain divided into four power sub-domains (labeled Q1 to Q4). Due to spatial variation across the chip, the largest minimum voltage needed to meet the target performance (e.g., target frequency) may be different in each sub-domain. The largest minimum supply voltage for each sub-domain is determined using the ring oscillators located in the power sub-domain. For example, the largest minimum voltage for sub-domain Q1 is determined using the ring oscillators located in sub-domain Q1.

In the example in FIG. 5, the largest minimum supply voltage for each of sub-domains Q1-Q3 is lower than the largest minimum supply voltage for sub-domain Q4. In other words, sub-domains Q1-Q3 are able to meet the target performance (e.g., frequency target) at a lower supply voltage than sub-domain Q4. As a result, the supply voltage for each of sub-domains Q1-Q3 is set to a lower voltage level than the supply voltage for sub-domain Q4. This reduces power compared to the prior approach in which the same supply voltage (i.e., supply voltage for sub-domain Q4) is used for the entire power domain.

In the example shown FIG. 5, the power domain (e.g., CX domain) is divided into four sub-domains Q1 to Q4. However, it is to be appreciated that the present disclosure is not limited to this example, and that the power domain may be divided into any number of power sub-domains (e.g., two sub-domains, eight sub-domains, etc.).

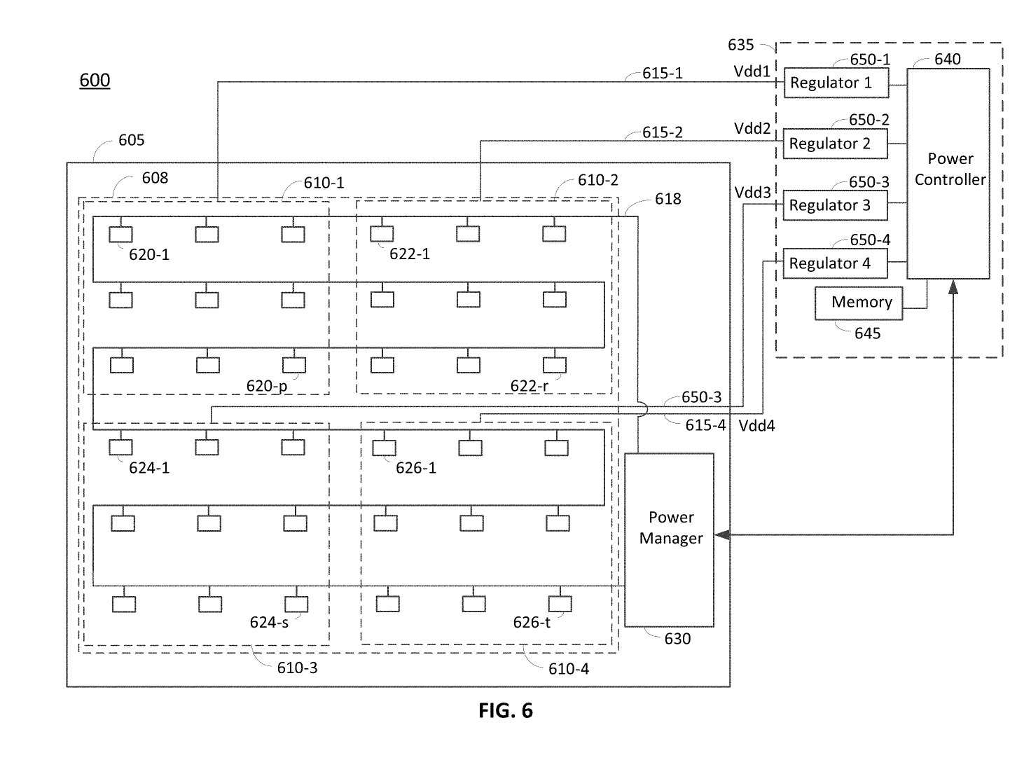

FIG. 6 shows an exemplary system 600 according to certain aspects of the present disclosure. In this example, the system 600 includes a chip (die) 605 and a programmable power source 635 (e.g. power management integrated circuit (PMIC)). The chip 605 includes a power manger 630, and a power domain 608 split into multiple power sub-domains 610-1 to 610-4.

The power source 635 includes multiple voltage regulators 650-1 to 650-4, a power controller 640, and a memory 645. The voltage regulators 650-1 to 650-4 are configured to provide supply voltages Vdd1 to Vdd4 for power sub-domains 610-1 to 610-4, respectively. The ground voltage is shared among all sub-domains. The power controller 640 may be configured to independently control the supply voltages provided by the voltage regulators 650-1 to 650-4, and therefore to independently control the supply voltages of the power sub-domains 610-1 to 610-4 of the chip 605. In one example, each of the voltage regulators 650-1 to 650-4 may be implemented with a switching regulator that converts a voltage from a battery or another source into the respective supply voltage. In this example, the power controller 640 may adjust the supply voltage provided by a voltage regulator by adjusting a duty cycle of the voltage regulator, or another parameter of the voltage regulator.

The power sub-domains 610-1 to 610-4 are coupled to the voltage regulators 650-1 to 650-4 via supply rails 615-1 to 615-4, respectively, as show in FIG. 6. Each power sub-domain includes one or more circuits (not shown) that are powered by the respective supply voltage. Although four power sub-domains 610-1 to 610-4 are shown in the example in FIG. 6, it is to be appreciated that the present disclosure is not limited to this example, and that the power domain 608 may be split into a different number of power sub-domains (e.g., two sub-domains, eight sub-domains, etc.). Also, although the power sub-domains 610-1 to 610-4 are shown having approximately the same size and shape for simplicity, it is to be appreciated that the power sub-domains 610 to 610-4 may have different sizes and/or shapes (e.g., depending on the layout of the chip).

In one example, the power domain 608 may be a core power domain (e.g., CX domain) for powering core logic on the chip. In this example, the supply voltages Vdd1 to Vdd4 of the sub-domains 610-1 to 610-4 may be set to different voltage levels to account for spatial variation across the power domain (e.g., CX domain), as discussed further below.

The chip 605 also includes multiple frequency measurement devices (depicted as small rectangles in FIG. 6) that are distributed across the chip 100 in order to measure spatial variation across the chip 605, as discussed further below. Each of the power sub-domains 610- to 610-4 includes a subset of the frequency measurement devices. More particularly, power sub-domain 610-1 includes frequency measurement devices 620-1 to 620-p, power sub-domain 610-2 includes frequency measurement devices 622-1 to 622-r, power sub-domain 610-3 includes frequency measurement devices 624-1 to 624-s, and power sub-domain 610-4 includes frequency measurement devices 626-1 to 626-t. The chip 605 also includes a communication bus 618 for providing communication between the frequency measurement devices and the power manager 630, as discussed further below.

Although, the frequency measurement devices are uniformly distributed across the chip 605 in the example shown in FIG. 6, it is to be appreciated that the present disclosure is not limited to this example. For example, the frequency measurement devices may be distributed non-uniformly due to constraints on where they can be placed on the chip 605. For instance, it may not be possible to place a frequency measurement device in an area of the chip that is densely populated by functional logic gates. In one example, the spacing between the frequency measurement devices may be between a hundred microns to several hundreds of microns (e.g., for 10 nm and 14 nm technologies) to capture spatial variation information.

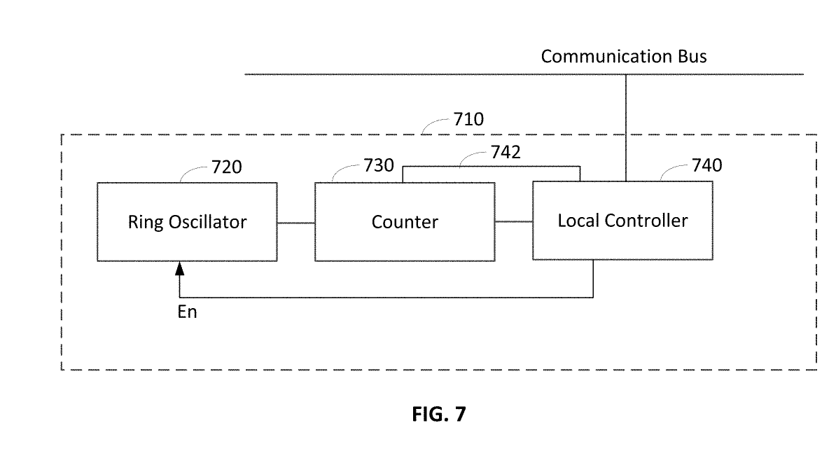

FIG. 7 shows an exemplary implementation of a frequency measurement device 710 according to certain aspects of the present disclosure. Each of the frequency measurement devices in FIG. 6 may be implemented using the frequency measurement device 710 shown in FIG. 7. In this example, the frequency measurement device 710 includes a ring oscillator 720, a counter 730, and a local controller 740. The ring oscillator 720 is preferably deep (e.g., includes a large number of inverting stages) to reduce random statistical variation, as discussed above. For example, the ring oscillator 720 may include 30 or more inverting stages.

The counter 730 is coupled to the output of the ring oscillator 720, and configured to count a number of oscillations at the output of the ring oscillator 720, as discussed further below. The local controller 740 is configured to control operation of the ring oscillator 720 and the counter 730, and to communicate frequency measurements with the power manager 630 via the communication bus 618, as discussed further below.

The frequency measurement device 710 is powered by the supply voltage of the power sub-domain in which the frequency measurement device 710 is located. For example, if the frequency measurement device 710 is located in power sub-domain 610-1, then the frequency measurement device 710 is powered by supply voltage Vdd1.

To make a frequency measurement, the local controller 740 enables the ring oscillator 720. For example, the local controller 740 may enable the ring oscillator 720 by asserting an enable signal (denoted “En”). Once enabled, the ring oscillator 720 outputs an oscillation signal to the counter 730 that oscillates at the oscillation frequency of the ring oscillator 720. The counter 730 then counts a number of oscillations of the oscillation signal over a predetermined period of time, and outputs the resulting count value to the local controller 740. The count value provides a digital measurement of the oscillation frequency of the ring oscillation 720. The higher the count value, the higher the oscillation frequency. The local controller 740 may temporarily store the count value in an internal register (not shown).

As discussed above, the counter 730 counts the number of oscillations of the ring oscillator 720 over a predetermined period of time. To do this, the local controller 740 may track the period of time using a timer. In this example, the local controller 740 may start the counter 730 at the beginning of the predetermined period of time, and stop the counter 730 at the end of the predetermined period of time. The local controller 740 may start and stop the counter 730 via a control line 742, as shown in FIG. 7. After the counter 740 stops, the local controller 740 may read the count value from the counter 730, and transmit the count value to the power manager 630, as discussed further below. The local controller 740 may then disable the ring oscillator 720 to conserve power. For example, the local controller 740 may disable the ring oscillator 720 by deasserting the enable signal En.

In certain aspects, the power manager 630 may command the frequency measurement device 710 to perform a frequency measurement by transmitting a measurement request to the frequency measurement device 710 via the communication bus 618. In response to the measurement request, the local controller 740 may operate the ring oscillator 720 and the counter 730 to perform the requested frequency measurement, as discussed above. The local controller 740 may then transmit the requested frequency measurement (i.e., count value) to the power manager 630 via the communication bus 618.

In certain aspects, the frequency measurement device 710 may be assigned a unique identification (ID). In these aspects, the power manager 630 may address (direct) a measurement request to the frequency measurement device by including the ID with the request. In these aspects, the local controller 740 may read the ID accompanying the request to determine whether the request is addressed to the frequency measurement device 710 (i.e., determine whether the ID accompanying the request matches the ID of the device). If the request is addressed to the frequency measurement device 710 (i.e., the ID accompanying the request matches the ID of the device), then the local controller 740 responds to the request, as discussed above. Otherwise, the local controller 740 may ignore the request. In this case, the request may be addressed to another frequency measurement device on the chip 605.

As discussed each of the frequency measurement devices on the chip 605 may be implemented using the exemplary frequency measurement device 710 shown in FIG. 7. In this example, each of the frequency measurement devices on the chip 605 may be a separate instance of the frequency measurement device 710 shown in FIG. 7 and may be assigned a different ID. This allows the power manager 630 to direct requests to different frequency measurement devices on the chip 605 via a common communication bus 618 using the IDs.

Returning to FIG. 6, the power manager 630 is configured to determine voltage level settings for the supply voltages Vdd1 and Vdd4 of the power sub-domains 610-1 to 610-4 for a particular target performance (e.g., target frequency) based on frequency measurements from the frequency measurement devices, as discussed further below.

A procedure for determining a supply voltage setting for one of the power sub-domains for a target frequency will now be described according to certain aspects. In this disclosure, the term “supply voltage setting” refers to the voltage level setting of the supply voltage.

The procedure includes the power manager 630 instructing the power controller 640 to sweep the supply voltage of the power sub-domain across a plurality of different voltage levels. For example, the power controller 640 may do this by sequentially setting the supply voltage to each one of the plurality of different voltage levels. The power controller 634 may set the voltage level of the supply voltage by setting a parameter (e.g., duty cycle) of the respective voltage regulator accordingly, as discussed above. For example, if the power manager 630 is determining the supply voltage setting for sub-domain 610-1, then the power controller 640 may adjust a parameter of voltage regulator 650-1 to set the voltage level of the supply voltage Vdd1.

For each of the voltage levels, the power manager 630 receives frequency measurements from the frequency measurement devices in the power sub-domain. For example, if the sub-domain is 610-1, then the power manager 630 receives frequency measurements from frequency measurement devices 620-1 to 620-p. The power manager 630 may receive the frequency measurements by sending measurement requests to the frequency measurement devices in the power sub-domain one-by-one via the communication bus 618, and receiving the corresponding frequency measurements from the frequency measurement devices one-by-one via the communication bus 618. As discussed above, the power manager 630 may address requests to frequency measurement devices using IDs. In this example, the power manager 630 may have knowledge of the IDs assigned to the frequency measurement devices located in the power sub-domain, and use this knowledge to address (direct) the measurement requests to the frequency measurement devices located in the power sub-domain.

For each of the voltage levels, the power manager 630 may compare the received frequency measurements for the voltage level with the target frequency to determine whether all of the frequency measurements meet the target frequency. If all of the frequency measurements are equal to or above the target frequency, then the power manager 630 may determine that the sub-domain meets the target frequency at the voltage level. If one or more of the frequency measurements are below the target frequency, then the power manager 630 may determine that the sub-domain does not meet the target frequency at the voltage level.

After determining whether the sub-domain meets the target frequency for each of the voltage levels, the power manager 630 may determine the lowest one of the voltage levels at which the sub-domain meets the target frequency.

In one example, the power manager 630 may instruct the power controller 640 to set the supply voltage of the sub-domain to an initial voltage level. The power controller 640 may then determine whether the sub-domain meets the target frequency at the initial voltage level as discussed above. If the sub-domain meets the target frequency, then the power manager 630 may decrease the sub-domain voltage setting and then check again to determine whether the sub-domain meets the target frequency. If the sub-domain does not meet the target frequency, then the power manager 630 may increase the sub-domain voltage setting and then check again to determine whether the sub-domain meets the target frequency. The power manger 630 may repeat this step until it finds a lowest voltage on the sub-domain that meets the target frequency.

The power manager 630 may use the lowest voltage level at which the sub-domain meets the target frequency as the voltage level setting for the supply voltage of the sub-domain at the target frequency. In another example, the power manager 630 may add a small voltage margin (guardband) to the lowest voltage level at which the sub-domain meets the target frequency, and use the resulting sum as the voltage level setting for the supply voltage of the sub-domain at the target frequency. The voltage margin (guardband) may be added to accommodate noise in the supply voltage.

Thus, the power manager 630 may perform the above procedure to determine a voltage level setting for the supply voltage of a power sub-domain for a particular target frequency. The power manager 630 may repeat the above procedure for each of the sub-domains 610-1 to 610-4 on the chip 605 to determine a voltage level setting for the supply voltage of each of the sub-domains 610-1 to 610-4 for the target frequency. The voltage level settings for the sub-domains 610-1 to 610-4 may be different due to the spatial variation discussed above.

The power manager 630 may write the voltage level settings for the sub-domains 610-1 to 610-4 in the memory 645 of the programmable power source 635. When circuits (e.g., core logic) in the sub-domains 610-1 to 610-4 are to operate at the target frequency, the power controller 640 may retrieve the voltage level settings for the sub-domains from the memory 645, and set the supply voltages for the sub-domains 610-1 to 610-4 at the respective voltage level settings. The circuits (e.g., core logic) may be operated at the target frequency by clocking the circuits with a clock signal having a clock frequency approximately equal to the target frequency. It is to be appreciated that the memory 645 may be located on the chip 605 instead.

Using separate supply voltage settings for the sub-domains 610-1 to 610-4 instead of a single supply voltage setting for the entire power domain allows the power manager to raise the supply voltage for a slow performing sub-domain without having to raise the supply voltages for the other sub-domains, thereby saving power. This also allows the power manager 630 to lower the supply voltage for a fast performing sub-domain below the supply voltages of the other sub-domains, thereby saving power.

In the discussion above, the procedure for determining the supply voltage setting for a sub-domain includes sweeping the supply voltage for the sub-domain across a plurality of different voltage levels. However, it is to be appreciated that the power manager 630 need not sweep through all of the voltage levels to determine the supply voltage setting for the sub-domain.

For example, the power manager 630 may start the supply voltage of the sub-domain at the lowest voltage level, and incrementally increase the voltage level of the supply voltage (e.g., by sequentially setting the supply voltage to different ones of the plurality of voltage levels in ascending order). For each voltage level, the power manager 630 may receive frequency measurements from the frequency measurement devices in the sub-domain, and determine whether the sub-domain meets the target frequency at the voltage level based on the frequency measurements, as discussed above. In this example, the power manager 630 incrementally increases the voltage level of the supply voltage until the sub-domain meets the target frequency. In other words, the power manager 630 stops increasing the voltage level of the supply voltage when the sub-domain meets the target frequency. When this occurs, the power manager 630 determines the supply voltage setting for the sub-domain based on the voltage level at which the sub-domain meets the target frequency. For example, the power manger 630 may use the voltage level at which the sub-domain meets the target frequency as the supply voltage setting for the sub-domain.

In another example, the power manager 630 may start the supply voltage of the sub-domain at the highest voltage level, and incrementally decrease the voltage level of the supply voltage (e.g., by sequentially setting the supply voltage to different ones of the plurality of voltage levels in descending order). For each voltage level, the power manager 630 may receive frequency measurements from the frequency measurement devices in the sub-domain, and determine whether the sub-domain meets the target frequency at the voltage level based on the frequency measurements, as discussed above. In this example, the power manager 630 incrementally decreases the voltage level of the supply voltage until the sub-domain no longer meets the target frequency. In other words, the power manager 630 stops decreasing the voltage level of the supply voltage when the sub-domain no longer meets the target frequency. When this occurs, the power manager 630 determines the supply voltage setting for the sub-domain based on the lowest voltage level at which the sub-domain meets the target frequency (e.g., the voltage level just one step above the voltage level at which the sub-domain fails to meet the target frequency). For example, the power manger 630 may use the lowest voltage level at which the sub-domain meets the target frequency as the supply voltage setting.

As discussed above, the supply voltage settings for the sub-domains 610-1 to 610-4 may be different due to spatial variation. If the differences between the supply voltage settings of the sub-domains 610-1 to 610-4 are small (e.g., 30 mV or less), then a signal may cross from one of the sub-domains to another one of the sub-domains without the need for voltage-level shifting between the sub-domains. If the differences between the supply voltage settings of the sub-domains 610-1 to 610-4 are larger (e.g., 100 mV or more), then voltage-level shifters may be needed for a signal to cross from one of the sub-domains to another one of the sub-domains.

In certain aspects, the power manager 630 may determine whether voltage-level shifters are needed for sub-domain crossings based on the differences between the supply voltage settings of the sub-domains 610-1 to 610-4. For example, the power manager 630 may determine the difference between the highest supply voltage setting for the sub-domains 610-1 to 610-4 and the lowest supply voltage setting for the sub-domains 610-1 to 610-4, and compare the difference with a threshold. If the difference is equal to or less than the threshold, then the power manager 630 may determine that voltage-level shifters are not needed for sub-domain crossings. If the difference is greater than the threshold, then the power manager 630 may determine that voltage-level shifters are needed for sub-domain crossings.

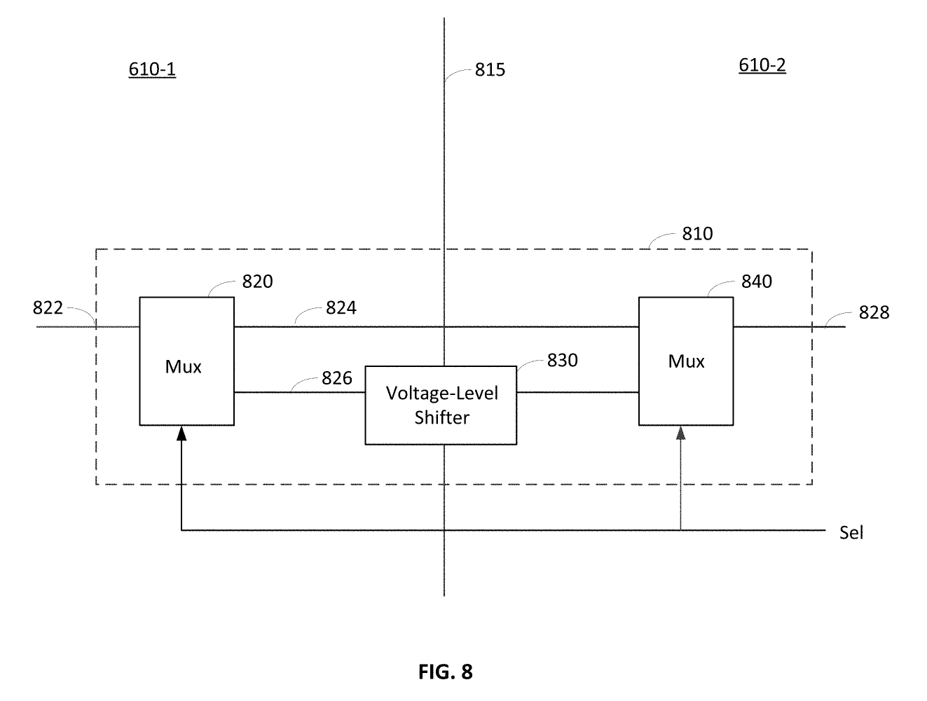

In this regard, FIG. 8 shows an exemplary interface 810 configured to send a signal across two sub-domains (e.g., sub-domains 610-1 and 610-2) according to certain aspects. In FIG. 8, the boundary between the two sub-domains is represented by line 815. In this example, the interface 810 includes a first multiplexer 820, a voltage-level shifter 830, and a second multiplexer 840. The interface 810 may be configured to cross a signal from sub-domain 610-1 to sub-domain 610-2. The first multiplexer 820 lies in sub-domain 610-1 and the second multiplexer 840 lies in sub-domain 610-2.

In this example, the voltage-level shifter 830 is configured to voltage-level shift a signal from the supply voltage level of sub-domain 610-1 to the supply voltage level of sub-domain 610-2. As shown in FIG. 8, the voltage-level shifter 830 may sit on the boundary 815 between the sub-domains and may receive the supply voltages of both sub-domains. The voltage-level shifter 830 may be implemented with a cross-coupled latch or another type of voltage-level shifter.

The first multiplexer 820 is configured to receive a signal (e.g., a data signal or clock signal) at input 822 from a circuit (not shown) in sub-domain 610-1. The first multiplexer 820 couples the received signal to one of first and second signal paths 824 and 826 according to a select signal (denoted “Sel”). The first signal path 824 crosses the sub-domain boundary without a voltage-level shifter (e.g., direct sub-domain crossing). The second signal path 826 also crosses the sub-domain boundary but includes the voltage-level shifter 830. The second multiplexer 820 is configured to receive the signal from one of the first and second signal paths 824 and 826 according to the select signal Sel, and to couple the received signal to output 828 for output to a circuit (not shown) in sub-domain 610-2.

In this example, the power manager 630 controls which one of the paths 824 and 826 of the interface 810 is used to cross a signal from sub-domain 610-1 to sub-domain 610-2 using the select signal Sel. For example, if the difference between the supply voltage levels of sub-domain 610-1 and sub-domain 610-2 is equal to or less than the threshold, then the power manager 630 may select the path 824 without the voltage-level shifter using the select signal Sel. In this case, the first multiplexer 820 couples the signal at input 822 to path 824, and the second multiplexer 840 couples the signal from path 824 to the output 828. Also, in this case, the voltage-level shifter 830 may be disabled (e.g., power to the voltage-level shifter 830 may be gated). If the difference between the supply voltage levels of sub-domain 610-1 and sub-domain 610-2 is greater than the threshold, then the power manager 630 may select the path 826 with the voltage-level shifter 830 using the select signal Sel. In this case, the first multiplexer 820 couples the signal at input 822 to path 826, and the second multiplexer 840 couples the signal from path 826 to the output 828.

The sub-domains 610-1 to 610-4 should not be confused with two power domains specifically designed to operate at different supply voltage levels for powering different types of devices (e.g., a core power domain for powering core logic and an input/output I/O power domain for powering I/O devices (e.g., I/O drivers and receivers) at a higher voltage level than the core logic). In the non-limiting example given above, the sub-domains 610-1 to 610-4 are part of the core power domain for powering core logic. As discussed above, the supply voltages of the sub-domains may be set at different voltage levels to account for spatial variation. The voltage range of the differences between the supply voltage settings of the sub-domains may be 150 mV or less, 100 mV or less, 50 mV or less, or 30 mV or less (e.g., depending on the process technology).

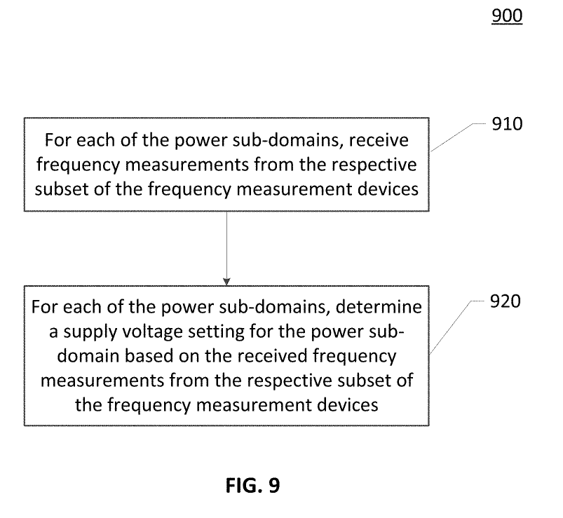

FIG. 9 is a flowchart illustrating a method 900 for power management of a chip according to certain aspects of the present disclosure. The chip (e.g., chip 605) includes frequency measurement devices distributed across a power domain (e.g., power domain 608) on the chip, wherein the power domain is divided into multiple power sub-domains (e.g., sub-domains 610-1 to 610-4), and each of the power sub-domains includes a respective subset of the frequency measurement devices.

The method includes 900, for each of the power sub-domains, receiving frequency measurements from the respective subset of the frequency measurement devices at step 910. For example, each frequency measurement device may include a ring oscillator (e.g., ring oscillator 120 or 720), and the frequency measurement from each frequency measurement device may include a measurement of the oscillation frequency of the respective ring oscillator.

The method 900 also includes, for each of the power sub-domains, determining a supply voltage setting for the power sub-domain based on the received frequency measurements from the respective subset of the frequency measurement devices at step 920. The supply voltage setting for each power sub-domain may be written to a memory (e.g., memory 645), which may include registers. A power controller (e.g., power controller 640) may read the supply voltage settings for the power sub-domains, and set the supply voltages (Vdd1 to Vdd4) for the sub-domains according to the respective supply voltage settings.

It is to be appreciated that the term “sub-domain” may also be referred to as simply “domain.” For example, the phrase “dividing a power domain into sub-domains” may also be referred to as “dividing a power domain into multiple smaller power domains.”

The power manger, local controller and power controller discussed above may be implemented with a general-purpose processor, a digital signal processor (DSP), an application specific integrated circuit (ASIC), a field programmable gate array (FPGA) or other programmable logic device, discrete hardware components (e.g., logic gates), or any combination thereof designed to perform the functions described herein. A processor may perform the functions described herein by executing software comprising code for performing the functions. The software may be stored on a computer-readable storage medium, such as a RAM, a ROM, an EEPROM, an optical disk, and/or a magnetic disk.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system, comprising:
frequency measurement devices distributed across a power domain on a chip, wherein the power domain is divided into multiple power sub-domains, and each of the power sub-domains includes a respective subset of the frequency measurement devices; and
a power manager, wherein, for each of the power sub-domains, the power manager is configured to:
receive frequency measurements from the respective subset of the frequency measurement devices; and
determine a supply voltage setting for the power sub-domain based on the received frequency measurements from the respective subset of the frequency measurement devices.

2. The system of claim 1, wherein each of the frequency measurement devices comprises a ring oscillator, and the frequency measurement from each of the frequency measurement devices comprises a measurement of an oscillation frequency of the respective ring oscillator.

3. The system of claim 2, wherein the ring oscillator comprises at least 30 inverting stages.

4. The system of claim 1, wherein the power domain is a core power domain for powering core logic on the chip.

5. The system of claim 1, wherein, for each of the power sub-domains, the power manager is configured to determine the supply voltage setting for the power sub-domain by:
instructing a power controller to sequentially set a supply voltage of the power sub-domain to each one of a plurality of different voltage levels;
for each of the voltage levels, receiving frequency measurements from the respective subset of the frequency measurement devices;
for each of the voltage levels, determining whether the power sub-domain meets a target frequency based on the received frequency measurements for the voltage level;
determining a lowest one of the voltage levels at which the power sub-domain meets the target frequency; and
determining the supply voltage setting for the power sub-domain based on the lowest one of the voltage levels at which the power sub-domain meets the target frequency.

6. The system of claim 5, wherein, for each of the power sub-domains, the supply voltage setting for the power sub-domain is approximately equal to the lowest one of the voltage levels at which the power sub-domain meets the target frequency.

7. The system of claim 5, wherein, for each of the power sub-domains, the power manager is configured to determine that the power sub-domain meets the target frequency for one of the voltage levels if all of the received frequency measurements for the voltage level meet the target frequency.

8. The system of claim 1, further comprising:
a plurality of voltage regulators, wherein each of the voltage regulators is configured to provide a supply voltage for a respective one of the power sub-domains; and
a power controller, wherein, for each of the power sub-domains, the power controller is configured to set a parameter of the respective voltage regulator to set the supply voltage for the power sub-domain according to the determined supply voltage setting for the power sub-domain.

9. The system of claim 8, wherein the power manager is configured to write the supply voltage setting for each of the power sub-domains in a memory accessible by the power controller.

10. The system of claim 8, wherein the voltage regulators and the power controller are external to the chip.

11. The system of claim 8, wherein the parameter comprises a duty cycle.

12. A method for power management of a chip, the chip including frequency measurement devices distributed across a power domain on the chip, wherein the power domain is divided into multiple power sub-domains, and each of the power sub-domains includes a respective subset of the frequency measurement devices, the method comprising:
for each of the power sub-domains, performing the steps of:
receiving frequency measurements from the respective subset of the frequency measurement devices; and
determining a supply voltage setting for the power sub-domain based on the received frequency measurements from the respective subset of the frequency measurement devices.

13. The method of claim 12, wherein each of the frequency measurement devices comprises a ring oscillator, and the frequency measurement from each of the frequency measurement devices comprises a measurement of an oscillation frequency of the respective ring oscillator.

14. The method of claim 13, wherein the ring oscillator comprises at least 30 inverting stages.

15. The method of claim 12, wherein the power domain is a core power domain for powering core logic on the chip.

16. The method of claim 12, wherein, for each of the power sub-domains, determining the supply voltage setting for the power sub-domain comprises:
sequentially setting a supply voltage of the power sub-domain to each one of a plurality of different voltage levels;
for each of the voltage levels, receiving frequency measurements from the respective subset of the frequency measurement devices;
for each of the voltage levels, determining whether the power sub-domain meets a target frequency based on the received frequency measurements for the voltage level;
determining a lowest one of the voltage levels at which the power sub-domain meets the target frequency; and
determining the supply voltage setting for the power sub-domain based on the lowest one of the voltage levels at which the power sub-domain meets the target frequency.

17. The method of claim 16, wherein, for each of the power sub-domains, the supply voltage setting for the power sub-domain is approximately equal to the lowest one of the voltage levels at which the power sub-domain meets the target frequency.

18. The method of claim 16, wherein, for each of the power sub-domains, determining whether the sub-domain meets the target frequency for one of the voltage levels comprises determining the sub-domain meets the target frequency for the voltage level if all of the received frequency measurements for the voltage level meet the target frequency.

19. The method of claim 12, further comprising setting a supply voltage for each of the power sub-domains according to the determined supply voltage setting for the power sub-domain using a respective voltage regulator.

20. The method of claim 19, wherein setting the supply voltage for each of the power sub-domains comprises setting a parameter of the respective voltage regulator.
